(19) United States
(12) Patent Application Publication
(10) Pub. No.: US 2018/0047873 A1
(43) Pub. Date: Feb. 15, 2018

(54) Radiation Body and Method for Producing a Radiation Body

(71) Applicant: OSRAM Opto Semiconductors GmbH, Regensburg (DE)

(72) Inventors: Philipp KREUTER, Regensburg (DE); Tansen VARGHESE, Regensburg (DE)

(21) Appl. No.: 15/552,470

(22) PCT Filed: Feb. 17, 2016
(86) PCT No.: PCT/EP2016/053361

§ 371 Date: Aug. 21, 2017

(30) Foreign Application Priority Data
Feb. 19, 2015 (DE) 10 2015 102 365.2

(51) Int. Cl. H01L 33/22; H01L 33/10

(52) U.S. Cl. CPC H01L 33/22; H01L 33/10; H01L 2933/0083; H01L 33/44

(57) ABSTRACT

A radiation body and a method for producing a radiation body are disclosed. In an embodiment, the radiation body includes a basic body configured to generate or absorb electromagnetic radiation, at least one main side having a rough structure of first elevations and at least one structured radiation surface structured with a fine structure of second elevations, wherein the fine structure brings about a gradual refractive index change for the radiation between materials adjoining the structured radiation surface, wherein the first elevations comprise heights and widths in each case of at least λₘₐₓ/n, wherein each second elevation tapers toward a maximum of the respective second elevation and each second elevations has a height of at least 0.6·λₘₐₓ/n and a width of λₘₐₓ/(2n) at most in each case, and wherein a distance between neighboring second elevations is λₘₐₓ/(2n) at most.

This patent application is a national phase filing under section 371 of PCT/EP2016/053361, filed Feb. 17, 20165, which claims the priority of German patent application 10 2015 102 365.2, filed Feb. 19, 2015, each of which is incorporated herein by reference in its entirety.

### TECHNICAL FIELD

A radiation body is provided. Furthermore, a method for producing a radiation body is provided.

Semiconductor bodies with structured radiation decoupling surfaces are known from US 2007/0065960 A1, for example.

### SUMMARY OF THE INVENTION

Embodiments of the invention provide a radiation body into which radiation can be particularly effectively coupled or from which radiation can be particularly effectively decoupled. Further embodiments provide a method for producing such a radiation body.

According to at least one embodiment, the radiation body comprises a basic body which generates or absorbs electromagnetic radiation when operated as intended, and then transforms it into an electronic or optical signal, for example. In particular, the radiation body can be electrically or optically pumped and emit radiation then.

In embodiments, the radiation body is a semiconductor body, e.g., an optoelectronic semiconductor body such as an electroluminescent light-emitting diode (LED), and the basic body is a semiconductor layer sequence having an active layer arranged in the semiconductor layer sequence. The semiconductor layer sequence is based on a III-V semiconductor compound material, for example. The semiconductor material is, for example, a nitride semiconductor compound material such as AlₙIn₁₋ₙ₋ₘGaₘN, or a phosphide semiconductor compound material such as AlₙIn₁₋ₙ₋ₘGaₘP, or an arsenide semiconductor compound material such as AlₙIn₁₋ₙ₋ₘGaₘAs or AlₙIn₁₋ₙ₋ₘGaₘAsP, with in each case 0≦n≦1, 0≦m≦1 and m+n≦1. Here, the semiconductor layer sequence may comprise dopants as well as additional components. For convenience, only the essential components of the crystal lattice of the semiconductor layer sequence, namely Al, As, Ga, In, N or P, are provided, even if these can partially be replaced and/or supplemented by small amounts of further substances. Preferably, the semiconductor layer sequence is based on AlInGaN or AlInGaAsP.

The active layer of the semiconductor layer sequence includes in particular at least one pn-transition and/or at least one quantum well structure, and can generate or absorb electromagnetic radiation when operated as intended, for example.

The basic body can also be based on a phosphor instead of a semiconductor layer sequence, or include or be an organic layer sequence.

A radiation generated by the basic body of the radiation body during operation in particular is in the spectral range between including 400 nm and 800 nm, or in the infrared range having wavelengths of at least 780 nm.

According to at least one embodiment, the radiation body comprises at least one main side which is provided with a rough structure (made) of first elevations. The rough structure preferably directly adjoins the basic body. The main side of the radiation body is a side of the radiation body having the greatest lateral extension. Incidentally, the main side is to be understood as an equalization plane through the rough structure, for example.

According to at least one embodiment, the radiation body comprises a radiation surface. The radiation surface is structured with a fine structure of second elevations arranged, e.g., periodically and/or regularly and/or uniformly on regular lattice points, for example. Here, the term periodical particularly means that each of the second elevations has the same distances to all directly neighboring second elevations within the scope of production tolerances. Preferably, the second elevations are arranged in the type of a matrix. Alternatively, it is also possible for the second elevations to be arranged a-periodically, the maximum distance between a second elevation and all directly neighboring second elevations preferably being no more than two times or no more than five times or no more than ten times the width of the second elevations.

According to at least one embodiment, radiation is decoupled from the radiation body or coupled into the radiation body via the structured radiation surface in such a way that the radiation passes the fine structure and the fine structure brings about a gradual and/or continuous and/or step-free refractive index change for the radiation between materials adjoining the radiation surface. The radiation surface particularly represents an interface between the radiation body and a medium adjoining the radiation body. If the material of the medium adjoining the radiation surface and the material of the radiation body adjoining the radiation surface have different refractive indices, an almost continuous refractive index change for the entering or exiting radiation is generated by the fine structure made of the second elevations. This advantageously reduces the Fresnel reflection at the radiation surface.

A gradual refractive index change particularly means that it is gradual on the scale of the wavelength or wavelengths of the radiation in the radiation body and/or adjoining medium. The materials of the radiation body adjoining the radiation surface and the materials of the adjoining medium are particularly materials or material combinations applied with a layer thickness on to the radiation surface which are at least 50% or 100% or 200% or 300% of the wavelength of the radiation in the corresponding material. In particular, a passivation layer of 50 nm or less can be applied on to the radiation surface with the fine structure, for example.

A medium adjoining the radiation body in the section of the radiation surface may adjoin the radiation surface only in the section of the maxima of the second elevations, for example. The interspaces between the elevations can be free of this material, for example. For example, these interspaces can be filled with air or gas bubbles.

According to at least one embodiment, the radiation decoupled from the radiation body or coupled into the radiation body has a global maximum of the radiation intensity at a main wavelength λₘₐₓ. The main wavelength λₘₐₓ is indicated for the radiation in vacuum.

According to at least one embodiment, the first elevations comprise heights and/or widths of in each case at least λₘₐₓ/n or at least 2·λₘₐₓ/n or at least 5·λₘₐₓ/n or at least 10·λₘₐₓ/n, with n being the refractive index of the material adjoining the radiation surface from which the radiation impinges on the radiation surface.

Here and in the following, a height of an elevation particularly means the maximum distance between a base area of the elevation and a maximum of the elevation. The width is measured parallel to the base area of the elevation and is the maximum or average width of the respective elevation, for example.

According to at least one embodiment, the second elevations each taper toward the maximum of the respective second elevation and comprise heights of at least 0.6·λₘₐₓ/n or at least λₘₐₓ/n or at least 2·λₘₐₓ/n, and widths of λₘₐₓ/(2n) at most or λₘₐₓ/(3n) at most or λₘₐₓ/(4n) at most. The distance between neighboring second elevations in particular is λₘₐₓ/(2n) at most or λₘₐₓ/(3n) at most or λₘₐₓ/(4n) at most. The distance of two elevations means, e.g., the distance between the maxima of the elevations or between the centroids of the base areas of the elevations or the minimal distance between side surfaces of the elevations.

The second tapering elevations may, for example, have the form of pyramids, cones, truncated cones, obelisks, lenses or hemispheres. The first elevations may comprise the same forms or further forms.

In at least one embodiment, the radiation body comprises a basic body which generates or absorbs electromagnetic radiation when operated as intended. Further, the radiation body includes at least one main side, which is provided with a rough structure of first elevations, and at least one radiation surface, which is structured with a fine structure of second elevations. The radiation is decoupled from the radiation body or coupled into the radiation body via the structured radiation surface in such a way that the radiation passes the fine structure and the fine structure brings about a gradual refractive index change between materials adjoining the radiation surface. Incidentally, the radiation has a global maximum of the radiation intensity at a main wavelength λₘₐₓ measured in vacuum. The first elevations comprise heights and widths of in each case at least λₘₐₓ/n, with n being the refractive index of the material from which the radiation impinges on the radiation surface. The second elevations each taper toward the maximum of the respective second elevations and comprise heights of at least 0.6·λₘa/n and widths of λₘₐₓ/(2n) at most. The distance between neighboring second elevations is in each case λₘₐₓ/(2n) at most.

Inter alia, the present invention is based upon the knowledge that the effectivity of the decoupling and coupling-in of radiation from or into a radiation body, e.g., a semiconductor body, is limited due to reflection effects. This is due to the fact that radiation impinging above the total reflection angle is completely reflected at the interfaces between radiation body and neighboring medium. However, below the total reflection angle, Fresnel reflections occur, in which only part of the radiation impinging on the interface is reflected. In such radiation bodies, these two mechanisms lead to a reduced effectivity of the radiation in-coupling or radiation decoupling.

Inter alia, the invention described here is based upon the idea of forming two different structures into the radiation body in order to thereby reduce both types of reflection, i.e., total reflection and Fresnel reflection. A rough structure having first elevations has a size in the range of the wavelength of the radiation, or greater. The impinging radiation is reflected at a new emission angle on such structures. This results in a re-distribution of the incident angle of the radiation on the radiation surface. In this way, the proportion of total reflection on the radiation surface can be reduced.

In addition, in the invention described here, a fine structure with second elevations is also used, the size of which is so small that the effect thereof for the impinging radiation must be evaluated no longer from a radiation-optical viewpoint, but from a wave-optical viewpoint. By the tapering of the second elevations, a gradual change between the refractive indices of the media or materials adjoining the radiation surface is produced for the impinging radiation. The proportion of Fresnel reflection can be reduced by such a gradual refractive index change, increasing the effectivity of decoupling or coupling-in for the radiation body.

According to at least one embodiment, the rough structure and/or the fine structure is/are formed of the material of the basic body, for example, of the material of the semiconductor layer sequence, of the phosphor or the organic layer sequence. In particular, the first and/or second elevations is/are based on the material of the base body directly adjoining the rough structure and/or the fine structure, e.g., on the semiconductor material of the semiconductor layer sequence. The semiconductor material may, for example, be one of the above-mentioned semiconductor materials.

According to at least one embodiment, the first elevations comprise heights and widths of 5 μm at most or 4 μm at most or 3 μm at most.

According to at least one embodiment, the active layer of the semiconductor layer sequence is based on GaAs or AlGaAs or AlInGaAsP and emits radiation in the infrared wavelength range with a main wavelength λₘₐₓ measured in vacuum of at least 950 nm or at least 1000 nm or at least 1050 nm when operated as intended.

According to at least one embodiment, the radiation body is configured for receiving electromagnetic radiation in the visible or infrared spectral range when operated as intended. The second elevations of the fine structure preferably comprise heights of at least 1.5·λₘₐₓ/n.

According to at least one embodiment, the rough structure and/or the fine structure is/are formed of a material different from the that of the basic body, for example, of the semiconductor layer sequence or of the phosphor or the organic layer sequence, or comprise a different material or consist of such a different material. The rough structure and/or the fine structure can then be applied on to the basic body as a separate layer, for example. The separate layer is structured with the first and/or second elevations then. For example, the separate layer is a layer of a silicone or a resin, or of silicon oxide, such as SiO₂, or of a titanium oxide, such as TiO₂. In this case, it is particularly advantageous if the refractive indices of the adjoining materials of the base body and of the rough structure and/or fine structure deviate from one another by 0.2 at most, or 0.1 at most, or 0.05 at most. In this way, it is prevented that an essential proportion of the radiation is reflected already on the interface between rough structure and/or fine structure and the basic body due to total reflection or Fresnel reflection.

According to at least one embodiment, the fine structure is arranged on the rough structure, which particularly means that the second elevations at least partially rise from side surfaces of the larger first elevations. In this case, the radiation surface and the main side of the radiation body are on the same side of the radiation body.

According to at least one embodiment, the first elevations widen in a direction away from the active layer at least in sections. In the widening sections of the first elevations, the peaks of the second elevations or maxima of the second elevations point in the main side direction then. The first elevations may then be formed as reversed truncated cones or truncated pyramids when seen from the main side of the radiation body, for example.

According to at least one embodiment, the main side of the radiation body with the rough structure is formed on a side of the radiation body opposite the radiation surface. The redistribution of the entrance angles of the entering or exiting radiation is effected on one side of the radiation body, the reduction of the Fresnel reflection through the fine structure is effected on the other side of the radiation body.

According to at least one embodiment, first elevations arranged next to one another comprise alternating heights and/or widths. Here, the heights and/or widths of two neighboring first elevations differ from one another by at least 30%, or at least 40%, or at least 50%, for example. The term alternating particularly means that larger first elevations and smaller first elevations alternate along the main side.

Incidentally, the first elevations can be arranged periodically and/or regularly and/or uniformly on lattice points, for example. Alternatively, it is also possible for the first elevations to be arranged a-periodic with an arbitrary or almost arbitrary or statistic distribution on the main side. It is also possible that all first elevations have identical sizes in height and/or width within the production tolerance.

According to at least one embodiment, a radiation-transmissive, e.g., transparent layer or a converter layer is applied on to the radiation surface. The radiation-transmissive layer or the converter layer form the medium adjoining the radiation surface. In particular, the layer thicknesses of the radiation-transmissive layer or of the converter layer are greater than 0.5·λₘₐₓ/n.

The converter layer particularly serves for causing a shift of the wavelength of the impinging or decoupled radiation. To that end, the converter layer may comprise a phosphor such as YAG or Sialon. The phosphors may, for example, be arranged in the form of luminescent particles in a silicone and/or epoxy and/or resin matrix. Alternatively, the converter layer may also be formed from ceramics. Silicones and/or resins and/or epoxides can be considered for the radiation-transmissive layer, for example.

In particular, the radiation-transmissive layer or the converter layer enclose the first and/or second elevations completely and encapsulate them. The first elevations and/or the second elevations are thus enclosed and covered below the radiation-transmissive layer or the converter layer in a form-fit manner.

According to at least one embodiment, the semiconductor layer sequence is based on GaN. In this case, the active layer of the semiconductor layer sequence preferably emits light in the blue or near ultra-violet range having wavelengths between 400 nm and 480 nm.

Furthermore, a method for producing a radiation body is provided. The method is particularly suitable for producing a radiation body described herein. In other words, all features disclosed in conjunction with the radiation body are also disclosed for the method and vice versa.

According to at least one embodiment, the method comprises a step A, in which a base body, e.g., of a semiconductor layer sequence, a phosphor or an organic layer sequence is provided. A radiation generated in the base body or impinging on the radiation body has a global maximum of the radiation intensity at a main wavelength λₘₐₓ measured in vacuum when operated as intended.

The base body for the production of the radiation body and the basic body of the radiation body can be identical.

In a step B, a rough structure made of first elevations is applied on to the main side of the base body.

In a further step C, a radiation surface with a fine structure of periodically arranged second elevations is formed into the base body, wherein radiation is decoupled from the radiation body or coupled into the radiation body via the structured radiation surface during operation. In this case, the first elevations preferably comprise heights and widths of in each case at least λₘₐₓ/n, with n being the refractive index of the material from which the radiation impinges on the radiation surface. The second elevations comprise heights of at least 0.6·λₘₐₓ/n and widths of λₘₐₓ/(2n) at most. The distance between neighboring second elevations is λₘₐₓ/(2n) at most, for example.

According to at least one embodiment, the rough structure and/or the fine structure is/are directly formed into the base body by means of a wet-chemical or dry-chemical etching method. However, it is also possible for the rough structure to be generated via a mechanical removal method, such as dicing or sawing. A structured lithography mask can be used for the wet-chemical or dry-chemical etching method, for example. Upon treatment with an etching agent, the structure of the lithography mask can be transferred to the base body.

Selective etching methods are also possible, which comprise different etching rates for different crystal directions, such as KOH etching. Here, a lithography mask can be omitted, since pyramid-like structures automatically form in the base body by the different etching rates for different crystal directions, for example.

According to at least one embodiment, the rough structure and/or the fine structure is/are applied on to the base body as a separate layer. The separate layer may comprise a material different from that of the base body, e.g., titanium oxide or silicon oxide. In particular, the separate layer can be structured prior to or after application on to the base body, e.g., by means of an etching method as mentioned above.

According to at least one embodiment, first auxiliary structures, for example, of SiO₂, are periodically applied on to the surface to be structured for forming the radiation surface structured with the fine structure. The widths of the auxiliary structures parallel to the surface to be structured are λₘₐₓ/(2n) at most, or λₘₐₓ/(3n) at most, or λₘₐₓ/(4n) at most, for example. For periodically applying the auxiliary structures, particularly auxiliary structures in the shape of spheres can be used, which spread on the surface to be structured preferably predominantly or completely in a single layer, being in direct contact to one another here. The spheres thus form a single-layered, most dense bead package on the surface to be structured. Interspaces in which the underlying surface to be structured is freely accessible remain between the auxiliary structures.

Subsequently, the section of the surface to be structured between the auxiliary structures can be etched more strongly than the sections below the auxiliary structures via a directed or an undirected etching method, for example. Thus, the auxiliary structures serve as a mask for the structuring. When applying an etching agent, the auxiliary structures can be etched as strong as or less than the surface to be structured so that after the etching process, overall second elevations remain below the auxiliary structures.

According to at least one embodiment, for forming the radiation surface structured with the fine structure, an etching method is used in which non-volatile residues remain on the surface to be structured due to occurring chemical reactions between etching agent and structured surface. These non-volatile residues can serve as a mask for the further etching method, whereby the second elevations remain after the etching method. The non-volatile residues can be based on organic compounds, for example. In particular, the non-volatile residues may form the above-mentioned auxiliary structures.

According to at least one embodiment, for forming the radiation surface structured with the fine structure, seeds are applied on to the surface to be structured during or after the growth of the base body, e.g., of the semiconductor layer sequence. In a subsequent step, the growth of the base body is continued, wherein the second elevations form from the material of the base body, e.g., the material of the semiconductor layer sequence, in the region of the seeds. Lattice defects formed in an intended or unintended manner on the surface to be structured may serve as seeds, for example. It is also possible to apply seeds on to the surface to be structured in an intended manner, for example, via a vapor liquid solid growth, VLS growth for short. Such a method is known from the document “Three-dimensional AlGaAs nano-heterostructures using both VLS and MOVPE growth mode” by K. Tateno, for example. Here, catalytically acting, liquid alloy drops are applied on to the surface to be structured. When subsequently introducing the reaction gases for forming the semiconductor layer sequence, this gas is absorbed on the surface of the drops and diffuse through the surface. Due to an oversaturation on the interface of the liquid drop and the underlying substrate of the surface to be structured, an accelerated crystal growth takes place, so that nanostructures are formed in the form of second elevations.

According to at least one embodiment, a stepper method is used for forming the radiation surface structured with the fine structure. Stepper methods are photolithographic structuring methods known in the semiconductor technology, in which a photolithographic mask is moved over the surface to be structured. Irradiation via optics results in a transfer of the structure of the mask to the surface to be structured.

According to at least one embodiment, self-aligning nanostructures are applied on to the surface to be structured for forming the radiation surface structured with the fine structure. These nanostructures may be present in the form of nanowires, for example. In particular, the nanostructures may comprise a material different from that of the base body, and be pre-fabricated. In other words, the nanostructures are not formed on the base body but are already present as nanostructures beforehand. The refractive index of the material of the nanostructures preferably deviates from the refractive index of the surface to be structured by 0.2 at most, or 0.1 at most, or 0.05 at most.

### BRIEF DESCRIPTION OF THE DRAWINGS

In the following, a radiation body described herein as well as a method for producing a radiation body is explained in detail with respect to the drawings using exemplary embodiments. Like reference characters indicate like elements throughout the figures. However, the drawings are not to scale and may rather show individual elements in an exaggerated size for a better understanding.

The Figures show in:

FIGS. 1 to 5 are cross-sectional views of exemplary embodiments of a radiation body, and

FIGS. 6A and 6B are cross-sectional views of exemplary embodiments of a radiation body in production.

### DETAILED DESCRIPTION OF ILLUSTRATIVE EMBODIMENTS

In the following, the radiation body is selected as an optoelectronic semiconductor body, the basic body as well as the base body are selected as semiconductor layer sequences. Alternatively, the radiation body can also be based on a phosphor or an organic layer sequence in all exemplary embodiments. The basic body and the base body are based on a phosphor or an organic layer sequence then, for example.

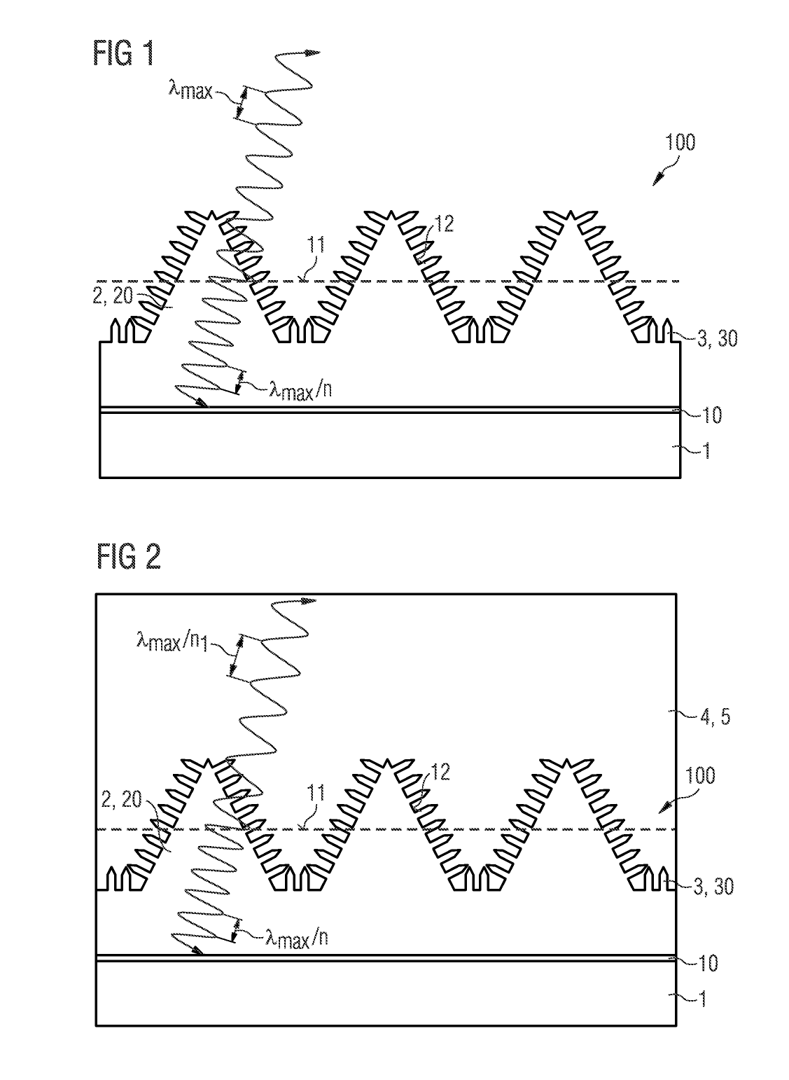

FIG. 1 shows an optoelectronic semiconductor body 100 in a cross-sectional view. The semiconductor body 100 comprises a semiconductor layer sequence 1 having an active layer 10. The active layer 10 can generate or absorb electromagnetic radiation when operated as intended. For example, the material of the semiconductor layer sequence 1 is GaAs or InGaAsP. The semiconductor body 100 further comprises a main side 11, which is provided with a rough structure 2 in the form of first elevations 20. Here, the main side 11 represented by a dashed line is an equalization plane running parallel to the active layer 10 through the first elevations 20. The first elevations 20 presently are formed pyramid-like and taper in the direction away from the active layer 10.

Furthermore, the semiconductor body 100 comprises a radiation surface 12 which is provided with a fine structure 3 of periodically arranged second elevations 30. In the case of FIG. 1, the radiation surface 12 is located on the rough structure 2. The second elevations 30 extend at least partially away from side surfaces of the first elevations 20. Here, the second elevations 30 are formed as obelisks, which taper toward the maximum of the respective second elevations 30. Alternatively, the second elevations 30 can also be formed as pyramids or cones or lenses or hemispheres.

FIG. 1 further shows electromagnetic radiation which is decoupled from the semiconductor body 100 or coupled into the semiconductor body 100. In the present case, a medium adjoining the semiconductor body 100 in the section of the radiation surface 12 is a vacuum, air or another gas having a refractive index of n_{gas}≈1. The radiation has, within the medium adjoining the semiconductor body 100, a main wavelength of λₘₐₓ at which the radiation intensity of the generated or received radiation has a global maximum. Within the semiconductor body 100, the main wavelength of the radiation is λₘₐₓ/n, with n being the refractive index of the material of the semiconductor layer sequence 1. Typical refractive indices of semiconductor layer sequences are in the range of n=2.5 and n=3.5. Due to the higher refractive index within the semiconductor material, the wavelength within the semiconductor body 100 is reduced with respect to the vacuum wavelength.

As can be seen from FIG. 1, the extensions of the first elevations 20, in particular the heights perpendicular to the main side 11 and the widths parallel to the main side 11, are greater than the wavelength λₘₐₓ of the radiation. However, the second elevations 30 of the fine structure 3 comprise heights and widths in the range of the vacuum main wavelength λₘₐₓ or the in-medium main wavelength λₘₐₓ/n. In the present case, the heights of the second elevations 30 are, e.g., at least λₘₐₓ/n, the widths of the second elevations 30 are λₘₐₓ/(2n) at most. Even the distances of neighboring second elevations 30 are λₘₐₓ/(2n) at most in this case.

Due to the relatively large dimensions of the rough structure 2, the radiation impinging on the rough structure 2 can be treated radiation-optically. By the reflection of the radiation at the rough structure 2, the entrance angle of the radiation is redistributed, whereby the proportion of total reflection on the radiation surface 12 is reduced. In contrast, the fine structure 3 is so small that wave-optical phenomena for the entering or exiting radiation have to be considered. In particular, the tapering of the second elevations 30 achieves that the fine structure 3 brings about a gradual refractive index change for the entering or exiting radiation between the medium adjoining the semiconductor body 100 in the section of the radiation surface 12 and the semiconductor body 100. In this way, Fresnel reflections, which occur when radiation impinges on the radiation surface 12, can be reduced by the fine structure 3.

FIG. 2 shows a similar exemplary embodiment as FIG. 1. In contrast to FIG. 1, a radiation-transmissive layer 5 or a converter layer 4 is applied on to the semiconductor body 100 in FIG. 2. The applied layer has a layer thickness of at least λₘₐₓ/n₁. In the present case, the material of the radiation-transmissive layer 5 or of the converter layer 4 has a refractive index of n₁, which is different from the refractive index n in the semiconductor body 100, for example. The converter layer 4 can be configured to convert radiation exiting from the semiconductor body 100 or entering the semiconductor body 100 into radiation of a different wavelength, e.g., by means of a phosphor such as YAG.

In the exemplary embodiment of FIG. 2, the rough structure 2 and the first elevations 20 thereof as well as also the fine structure 3 and the second elevations 30 thereof are completely covered and enclosed by the radiation-transmissive layer 5 or the converter layer 4. However, interspaces containing air or gas bubbles may remain between the individual second elevations 30.

The radiation-transmissive layer 5 or the converter layer 4 can, but need not copy the second elevations 30 in a form-fit manner.

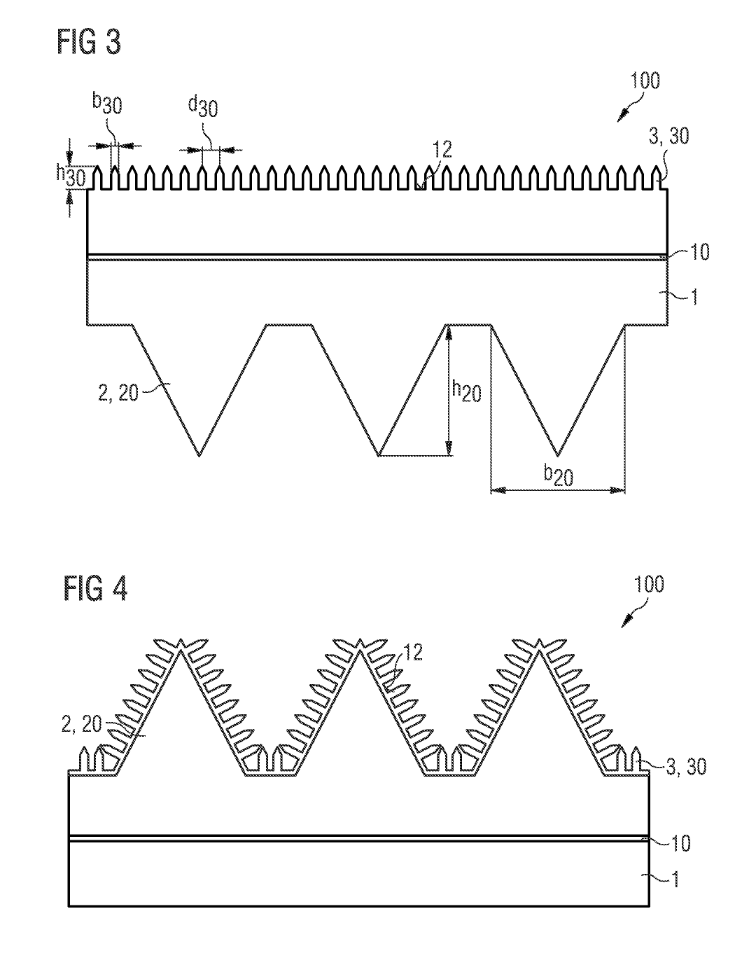

In the exemplary embodiment of FIG. 3, in contrast to the exemplary embodiment of FIG. 1, the main side 11 having the rough structure 2 is formed on a side of the active layer 10 opposite the radiation surface 12 having the fine structure 3. The re-distribution of the entrance angles of the radiation impinging on the radiation surface 12 is thus achieved on the rear side of the semiconductor body 100 via the rough structure 2, the decoupling via the radiation surface 12 is effected via the opposite front side.

For illustration, the heights h₂₀ and widths b₂₀ of the first elevations 20 as well as the heights h₃₀, widths b₃₀ and distances d₃₀ of the second elevations 30 are also indicated in FIG. 3. The heights are in each case measured from the base area of the respective elevation to the maximum of the respective elevation. In the present case, the widths are the maximum widths parallel to the base area of the respective elevation. The distances d₃₀ are the distances of the maxima or peaks of the second elevations 30.

In the exemplary embodiment of FIG. 4, in contrast to the exemplary embodiment of FIGS. 1 to 3, the fine structure 3 having the second elevations 30 is not of the same material as the semiconductor layer sequence 1. In this case, the fine structure 3 having the second elevations 30 is directly applied on to the semiconductor layer sequence 1 as a separate layer. Here, the refractive index of the material of the fine structure 3 is different from the refractive index of the material of the semiconductor layer sequence 1 by less than 0.1. For example, the semiconductor layer sequence 1 is based on GaN, the fine structure 3 having the second elevations 30 is based on titanium oxide.

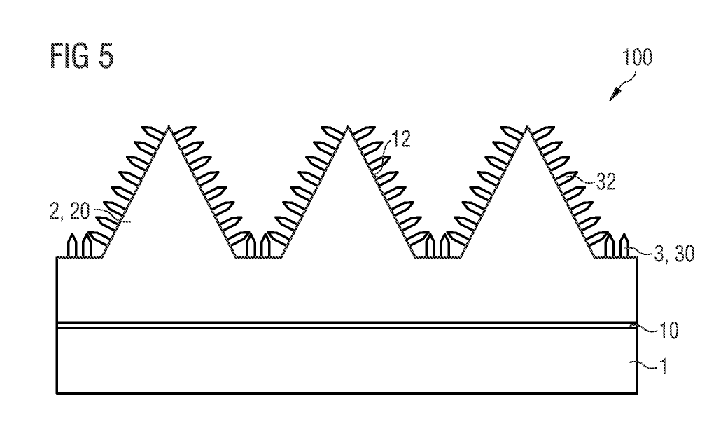

In the exemplary embodiment of FIG. 5, the first elevations 30 are formed in the form of nanostructures 32, which are based on a material different from that of the semiconductor layer sequence 1. The nanostructures 32 can, e.g., be applied on to the surface of the rough structure 3 and self-organize there and thus form the periodically arranged first elevations 30. For example, the refractive index of the nanostructures 32 differs from the refractive index of the semiconductor layer sequence 1 by 0.2 at most. For the nanostructures 32, in particular nanotubes or nano-cones can be considered, which are based on an organic material or a semiconductor material such as GaAs, for example.

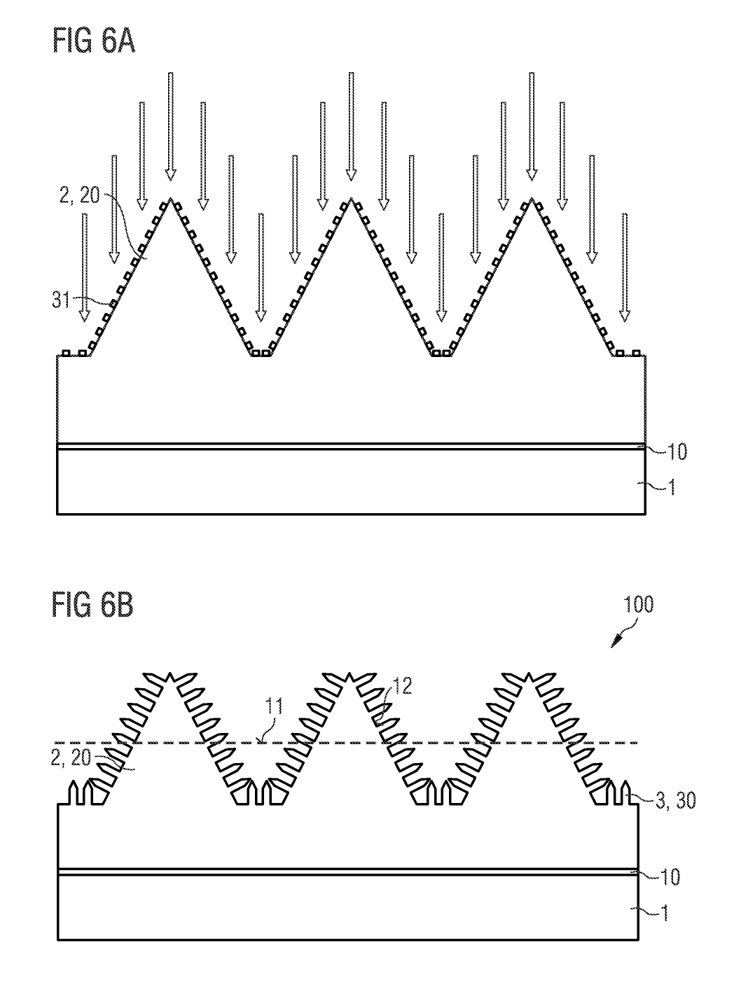

The exemplary embodiments of FIGS. 6A and 6B show different method steps for producing an optoelectronic semiconductor body 100. In FIG. 6A, a main side 11 of the semiconductor layer sequence 1 is already provided with a rough structure 2 of first elevations 20. The rough structure 2 can be formed into the semiconductor layer sequence 1, e.g., via a wet-chemical or dry-chemical etching method using a lithographic mask, for example. In the method step shown in FIG. 6A, auxiliary structures 31 are applied on to the rough structure 2, in particular on to the side walls of the second elevations 20. The auxiliary structures 31 can be, e.g., silicon oxide beads, which are applied after forming the rough structure. The silicon oxide beads can be in direct contact to one another and preferably be applied on to the rough structure 2 in a single layer. In the subsequent etching process, the sections of the semiconductor layer sequence 1 between the auxiliary structures 31 are etched more than the sections below the auxiliary structures 31. As a result, as shown in FIG. 6B, second elevations 30 are obtained, forming the fine structure 3 of the radiation surface 12.

The invention is not limited to exemplary embodiments by the description by means of these exemplary embodiments. Rather, the invention includes each new feature as well as each combination of features, which particularly includes each combination of features in the claims, even if these features or these combinations are per se not explicitly specified in the claims or exemplary embodiments.

1-17. (canceled)

18. A radiation body comprising:
a basic body configured to generate or absorb electromagnetic radiation;
at least one main side having a rough structure of first elevations; and
at least one structured radiation surface structured with a fine structure of second elevations,
wherein the radiation is decoupled from the radiation body or coupled into the radiation body via the structured radiation surface such that the radiation passes the fine structure and the fine structure brings about a gradual refractive index change for the radiation between materials adjoining the structured radiation surface,
wherein the radiation has a global maximum of radiation intensity at a main wavelength λₘₐₓ measured in vacuum,
wherein the first elevations comprise heights and widths in each case of at least λₘₐₓ/n,
wherein n is the refractive index of a material from which the radiation impinges on the structured radiation surface,
wherein each second elevation tapers toward a maximum of the respective second elevation and each second elevations has a height of at least 0.6·λₘₐₓ/n and a width of λₘₐₓ/(2n) at most in each case, and
wherein a distance between neighboring second elevations is λₘₐₓ/(2n) at most.

19. The radiation body according to claim 18,
wherein the radiation body is an optoelectronic semiconductor body in form of an electro-luminescent light-emitting diode,
wherein the basic body is a semiconductor layer sequence having an active layer configured to generate electromagnetic radiation,
wherein the fine structure is made from a material of the basic body,
wherein the first elevations have heights and widths of 5 μm at the most, and
wherein the active layer is based on GaAs, AlGaAs or InAlGaAsP and configured to generate radiation in an infrared wavelength range with a main wavelength λₘₐₓ of at least 950 nm measured in vacuum.

20. The radiation body according to claim 18,
wherein the fine structure is made from the material of the basic body,
wherein the radiation body is configured to receive electromagnetic radiation in a visible spectral range or an infrared spectral range, and
wherein the second elevations of the fine structure have heights of at least 1.5·λₘₐₓ/n.

21. The radiation body according to claim 18,
wherein the rough structure and/or the fine structure is/are made from a material different from a material of the basic body, and
wherein refractive indices of the adjoining materials of the basic body and the rough structure and/or the fine structure deviate from one another by 0.2 at the most.

22. The radiation body according to claim 18,
wherein the fine structure is arranged on the rough structure and the second elevations at least partially rise from side surfaces of the first elevations, and
wherein the first elevations widen at least in sections in the direction away from an active layer so that peaks of the second elevations point in the direction of the main side in these widening sections.

23. The radiation body according to claim 18,
wherein the main side with the rough structure is formed on a side of the radiation body opposite the structured radiation surface.

24. The radiation body according to claim 18,
wherein first elevations arranged next to one another have alternating heights and/or widths with deviations in the heights and/or widths of at least 30%.

25. The radiation body according to claim 18,
wherein a radiation-transmissive layer or a converter layer for shifting the wavelength of the impinging or decoupled radiation is applied on to the structured radiation surface, and
wherein the radiation-transmissive layer or the converter layer completely encloses and encapsulates the first and/or second elevations.

26. The radiation body according to claim 18,
wherein the basic body is based on GaN; and
wherein the rough structure and the fine structure are based on titanium oxide.

27. A method for producing a radiation body, the method comprising:
providing a base body, wherein, when operated as intended, radiation generated in the base body or impinging on the radiation body has a global maximum of s radiation intensity at a main wavelength λₘₐₓ measured in vacuum;
applying a rough structure of first elevations to a main side of the base body; and
forming a structured radiation surface with a fine structure of second elevations, wherein the radiation is decoupled from the radiation body or coupled into the radiation body via the structured radiation surface,
wherein the first elevations comprise heights and widths in each case of at least λₘₐₓ/n,
wherein n is a refractive index of a material from which the radiation impinges on the structured radiation surface,
wherein the second elevations comprise heights of at least 0.6·λₘₐₓ/n and widths of λₘₐₓ/(2n) at most,
wherein a distance between neighboring second elevations is λₘₐₓ/(2n) at most, and
wherein the rough structure and/or the fine structure are applied to the base body as a separate layer.

28. The method according to claim 27,
wherein the base body is a semiconductor layer sequence having an active layer which generates or absorbs electromagnetic radiation when operated as intended, and
wherein the rough structure and/or the fine structure is/are formed into the base body by wet-chemical etching or a dry-chemical etching.

29. The method according to claim 27,
wherein the separate layer comprises a material different from that of the base body, and
wherein the separate layer is structured prior to or after application on to the base body.

30. The method according to claim 27, wherein forming the structured radiation surface comprises:
periodically applying auxiliary structures to the surface to be structured, wherein the auxiliary structures comprise widths parallel to the surface of λₘₐₓ/(2n) at most; and
subsequently performing a directed or undirected etching, wherein etching etches sections of the surface to be structured between the auxiliary structures more than sections below the auxiliary structures thereby forming the second elevations.

31. The method according to claim 27, wherein forming the structured radiation surface comprises performing etching, in which nonvolatile residues remain on the surface to be structured due to an occurrence of an chemical reaction during etching, wherein the nonvolatile residues form auxiliary structures.

32. The method according to claim 27, wherein forming the structured radiation surface structured comprises:
placing seeds on the surface to be structured during or after growth of the base body; and
subsequently continuing the growth of the base body, wherein the second elevations are formed from the material of the base body in section of the seeds.

33. The method according to claim 27,
wherein a stepper method is used for forming the structured radiation surface structured with the fine structure.

34. The method according to claim 27, wherein forming the structured radiation surface comprises applying self-aligning nanostructures to the surface to be structured, wherein the refractive index of a material of the nanostructures deviates from the refractive index of the surface to be structured by less than 0.2.

35. A radiation body comprising:
a basic body configured to generate or absorb electromagnetic radiation;
at least one main side provided with a rough structure of first elevations; and
at least one radiation structured surface structured with a fine structure of second elevations,
wherein the radiation is decoupled from the radiation body or coupled into the radiation body via the structured radiation surface such that the radiation passes the fine structure and the fine structure brings about a gradual refractive index change for the radiation between materials adjoining the structured radiation surface,
wherein the radiation has a global maximum of a radiation intensity at a main wavelength λₘₐₓ measured in vacuum,
wherein the first elevations comprise heights and widths in each case of at least λₘₐₓ/n,
wherein n is the refractive index of the material from which the radiation impinges on the structured radiation surface,
wherein each second elevation tapers toward a maximum of the respective second elevation and each has a height of at least 0.6·λₘₐₓ/n and a width of λₘₐₓ/(2n) at most,
wherein a distance between neighboring second elevations is λₘₐₓ/(2n) at most, and
wherein the rough structure and/or the fine structure is applied to the basic body as a separate layer.

36. The radiation body according to claim 35, wherein the separate layer is a layer of silicone, a resin, a silicon oxide or a titanium oxide.
